(19) United States
(12) Patent Application Publication
(10) Pub. No.: US 2025/0306120 A1
(43) Pub. Date: Oct. 2, 2025

(54) SYSTEM AND METHODS FOR TESTING OF A RECHARGEABLE BATTERY

(71) Applicant: Cox Automotive, Inc., Atlanta, GA (US)

(72) Inventor: Bryan Schultz, Atlanta, GA (US)

(21) Appl. No.: 18/622,296

(22) Filed: Mar. 29, 2024

(51) Int. Cl. G01R 31/392; G01R 31/378; G01R 31/385

(52) U.S. Cl. CPC G01R 31/392; G01R 31/378; G01R 31/385

(57) ABSTRACT

System and method for testing of a rechargeable battery is provided. The system includes a power cycler having a negative terminal and a positive terminal. The rechargeable battery includes a negative terminal and a positive terminal. The negative terminal of the rechargeable battery is connected to the negative terminal of the power cycler. An opposition battery includes a negative terminal and a positive terminal. The positive terminal of the opposition battery is connected to the positive terminal of the rechargeable battery. The negative terminal of the opposition battery is connected to the positive terminal of the power cycler. The power cycler is configured to inject a predetermined amount of current to the rechargeable battery.

### BACKGROUND

Electrochemical devices, for example, a rechargeable battery, a storage battery, a secondary cell, or an accumulator is a type of electrical battery that can be charged, discharged into a load, and recharged many times. Rechargeable batteries are produced in many different shapes and sizes, ranging from button cells to large systems connected to stabilize an electrical distribution network. Several different combinations of electrode materials and electrolytes are used, including lead-acid, nickel cadmium (NiCd), nickel metal hydride (NiMH), lithium ion (Li-ion), and lithium ion polymer (Li-ion polymer).

Rechargeable batteries are used for many applications including powering automobiles, portable consumer devices, light vehicles (such as motorized wheelchairs, golf carts, electric bicycles, and electric forklifts), tools, and uninterruptible power supplies. Emerging applications in hybrid internal combustion-battery and electric vehicles are driving the technology to reduce cost, weight, size, and increase lifetime.

The rechargeable batteries used in the automotive industry are sometimes recalled or swapped out by automotive dealers. Not all recalled and swapped out rechargeable batteries are degraded. Therefore, these rechargeable batteries are tested to determine a level of degradation.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion. In addition, the drawings are illustrative as examples of embodiments of the invention and are not intended to be limiting.

FIG. 1 is a diagram of a system for testing a rechargeable battery.

FIG. 2 is a diagram illustrating modules of a battery under test.

FIG. 3 is a diagram illustrating sections of a battery under test.

FIG. 4 is a flow diagram of a method of testing a rechargeable battery.

FIG. 5 is a block diagram of a computing device.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Embodiments of the disclosure provide system and method for testing of electrochemical devices, for example, a rechargeable battery. The system and method disclosed herein enable testing of a rechargeable battery at a lower rated grid connection facility. The system includes a power cycler and an opposition battery. The rechargeable battery (also referred to as a battery under test) is connected to the power cycler. The opposition battery is connected to the battery under test such that the opposition battery is in opposition to the battery under test. The battery under test and the opposition battery, however, together act like a single battery from the power cycler point of view with a lower voltage rating.

The system further includes a first controller and a second controller. The first controller provides feedback to and controls the power cycler. The second controller controls the opposition battery. During testing, the power cycler injects a predetermined amount of current through the battery under test. Parameters of the battery under test are measured based on a response to the injected current. As discussed in the following portions of the disclosure, the opposition battery enables the power cycler to inject an increased or a higher amount of current through the battery under test. In addition, the opposition battery allows for testing of the battery under test without having a higher capacity electrical grid connection at a testing facility.

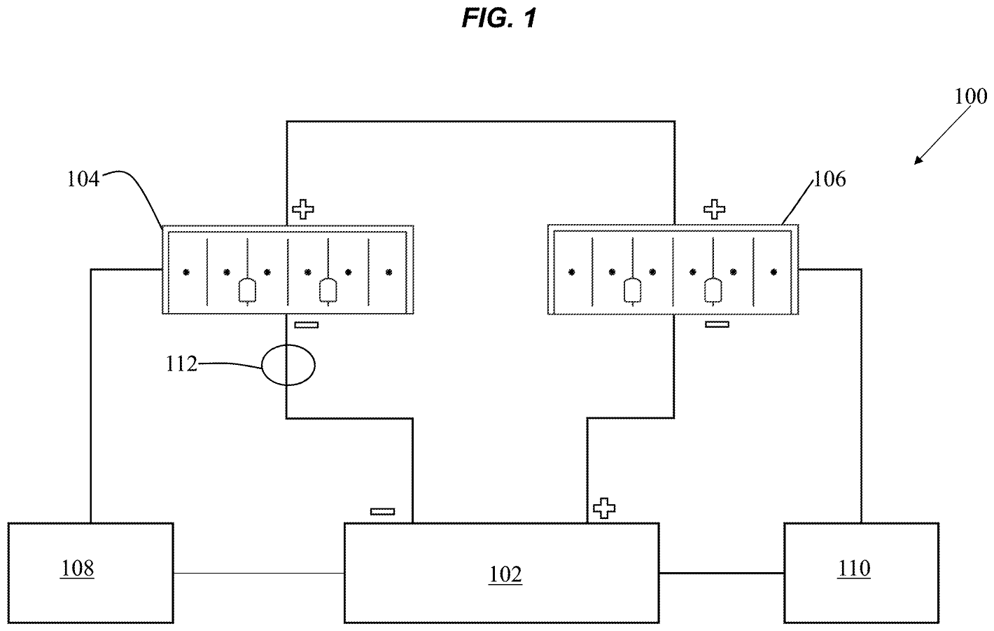

FIG. 1 is a diagram of a system 100 for testing a rechargeable battery (also referred to as a battery under test). As shown in FIG. 1, system 100 includes a power cycler 102, a battery under test 104, an opposition battery 106, a first controller 108, and a second controller 110. In some examples, first controller 108 may be part of power cycler 102 and second controller 110 may be part of opposition battery 106. System 100 may further include a plurality of sensors 112 (only one shown). Plurality of sensors 112 may include, for example, a charge sensor, a current sensor, a voltage sensor, a temperature sensor etc. In some examples, plurality of sensors 112 may be part of power cycler 102. System 100 may be located at a battery testing facility or a battery recycling facility, and may also be referred to as a test bed or test stand.

A negative terminal of power cycler 102 is connected to a negative terminal battery under test 104. A positive terminal of battery under test 104 is connected to a positive terminal of opposition battery 106. A negative terminal of opposition battery 106 is connected to a positive terminal of power cycler 102. Thus, opposition battery 106 is connected in opposition to battery under test 104. In addition, battery under test 104 and opposition battery 106 in combination are seen as a single battery pack from power cycler 102 point of view. As discussed in greater details in the following parts of the specification, adding opposition battery 106 to system 100 improves testing capability of power cycler 102.

First controller 108 is connected to both power cycler 102 and battery under test 104. First controller 108 may control and provide feedback to power cycler 102 regarding a current state of battery under test 104. Second controller 110 is connected to both power cycler 102 and opposition battery 106. Second controller 110 is configured to change a configuration of opposition battery 106. For example, second controller 110 can dynamically increase or decrease a capacity of opposition battery 106 during testing of battery under test 104. In some examples, first controller 108 is also connected to second controller 110 and can instruct second controller 110 to change a configuration of opposition battery 106. In some other examples, second controller 110 is not connected to power cycler 102.

Power cycler 102, in example embodiments, is configured to inject/withdraw a predetermined amount of current to/from battery under test 104. Power cycler 102, thus, can charge or discharge battery under test 104 by injecting current into or withdrawing current from battery under test 104. Power cycler 102 is connected to a power grid through a grid connection. Power cycler 102 sources power for charging battery under test 104 and opposition battery 106 from the power grid. In addition, power cycler 102 can recycle any power harvested during discharging of battery under test 104 and opposition battery 106 back to the power grid through the grid connection.

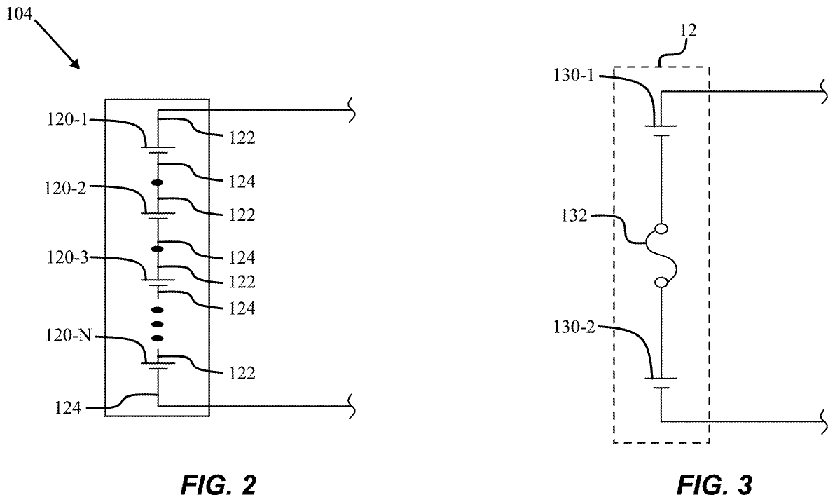

Battery under test 104 is a rechargeable battery. In some embodiments, battery under test 104 is recovered from a vehicle, for example, an electric vehicle. Battery under test 104 may include a plurality of battery modules connected together. In examples, a module may be the smallest unit of battery under test 104 without breaking any permanent mechanical structure. FIG. 2 illustrates an example battery under test 104. As shown in FIG. 2, battery under test 104 may include a plurality of battery modules, 120-1, 120-2, 120-3, . . . , 120-N connected together. It may be understood that battery under test 104 may include any number of battery modules. For example, battery under test 104 may include 28, 30, 38, 40, or 48 battery modules.

Each of the plurality of battery modules have a positive terminal 122 and a negative terminal 124. The plurality of battery modules can be combined in a series configuration in which positive terminal 122 of one of the plurality of battery modules is connected to negative terminal 124 of an adjacent battery module. In some arrangement, one or more battery modules are connected in parallel while some battery modules are connected in series. A total capacity and voltage rating of battery under test 104 may depend on a number of battery modules included in battery under test 104 and connection configuration of the battery modules. Each of the plurality of battery modules may include one or more cells connected together. A capacity and voltage rating of a battery module may depend on a number of battery cells included in the battery module and connection configuration of the battery cells.

In some examples, one or more fuses may divide battery under test 104 into two or more sections or groupings. Battery sections are generally composed of a plurality of modules and may be structured for ease in disassembly and reconstituted through the use of removable hardware (e.g., threaded rods with removable nuts). These structures may arise for two reasons. First is the requirement for mechanical compression which may be required for proper functioning. Second, intermediate electrical equipment, such as fuses and contactors, are positioned for safety and operation. For example, fuses are typically located mid-battery pack so that removal of the fuse reduces battery voltage by half.

FIG. 3 is a diagram illustrating sections of battery under test 104. As shown in FIG. 3, battery under test 104 includes two sections, a first section 130-1 and a second section 130-2 connected by a fuse 132. Each of first section 130-1 and second section 130-2 may include multiple battery modules, for example, 28, 30, 38, 40, etc. A number of battery modules in each of first section 130-1 and second section 130-2 may be same or different depending on a design consideration of battery under test 104. In addition, battery under test 104 may include more than two modules and the modules do not have to be separated by fuse 132. Moreover, in some examples, if present, fuse 132 does not have to be between sections, and can be located anywhere along a current path. For example, fuse 132 can be located anywhere on exterior of battery under test 104 so that fuse 132 is more accessible by a user.

Referring back to FIG. 1, opposition battery 106 may be similar in configuration to battery under test 104. For example, opposition battery 106 may include a plurality of battery modules, battery section, or a combination of battery modules and battery sections connected together. The plurality of battery modules for opposition battery 106 may be assembled from different battery packs. A total capacity and voltage rating of opposition battery 106 may depend on a number of battery modules included in battery under test 104 and connection configuration of the battery modules.

A capacity of opposition battery 106 may be determined for each test and may depend on a capacity of power cycler 102 and battery under test 104. For example, a capacity of opposition battery 106 may be n-times of a capacity of battery under test 104, where n is predefined range. In one example, if battery under test 104 is rated at 60 KWH then opposition battery 106 may be rated at 300 KWH (that is, 5 times) or higher.

In an embodiment, a voltage rating of opposition battery 106 is lower than the voltage rating of the battery under test 104. A difference in the voltage ratings of battery under test 104 and opposition battery 106 may depend on ratings of power cycler 102 and capacity of the grid connection available at the test facility. In on example, a voltage output of power cycler 102 must be higher than that of a difference between battery under test 104 and opposition battery 106 voltage ratings, but not higher than a predetermined limit. The greater the difference between the voltage rating of power cycler 102 and the difference between battery under test 104 and opposition battery 106 voltage rating, the faster the charging process, but also the greater the risk of overcharging and damaging battery under test 104. In one example, if battery under test 104 is rated at 800V then opposition battery 106 may be rated at 700V. In this example, a voltage difference at terminals of power cycler 102 is 100V. In other examples, a voltage difference at terminals of power cycler 102 can be 50V, 150 V, 200V, etc.

The voltage difference at the terminals of power cycler 102 and the capacity of opposition battery 106, may be based on the capacity of the grid connection at the testing facility. For example, a lower voltage difference and, hence, a higher capacity and a higher voltage rated opposition battery 106 is used for a lower capacity grid connection. On the contrary, a higher voltage difference and, hence, a lower capacity and a lower voltage rated opposition battery 106 may be used for a higher capacity grid connection.

Plurality of sensors 112 may be connected to battery under test 104. In some examples, each of plurality of battery modules of battery under test 104 may have its own set of sensors. In some other examples, each battery sections of battery under test 104 may have its own set of sensors. Each of plurality of sensors 112 may measure respective parameters for battery under test 104, respective battery module, or respective section, provide the measured parameters to first controller 108. In some examples, the measured parameters are also provided to power cycler 102.

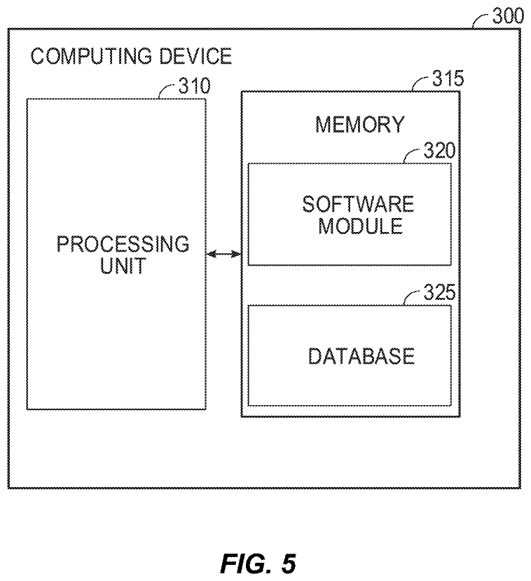

The elements described above of operating environment 100 (e.g., power cycler 102, first controller 108, second controller 110, and plurality of sensors 112) may be practiced in hardware and/or in software (including firmware, resident software, micro-code, etc.) or in any other circuits or systems. The elements of operating environment 100 may be practiced in electrical circuits comprising discrete electronic elements, packaged or integrated electronic chips containing logic gates, a circuit utilizing a microprocessor, or on a single chip containing electronic elements or microprocessors. Furthermore, the elements of operating environment 100 may also be practiced using other technologies capable of performing logical operations such as, for example, AND, OR, and NOT, including but not limited to, mechanical, optical, fluidic, and quantum technologies. As described in greater detail below with respect to FIG. 5, the elements of operating environment 100 may be practiced in a computing device 300.

Two different types of tests can be performed through system 100 on battery under test 104: a pulse test and a cycle test. During the pulse test, a high current (also referred to as a pulse current) is applied to battery under test 104 for a short time period. The pulse test simulates stressful or extreme operating conditions for battery under test 104. The amount of current to be applied and the time period for the pulse test is determined based on the specification of battery under test 104. In addition, the amount of current and the time period for the pulse test may also depend on the rating of power cycler 102, opposition battery 106, and the grid connection at the test facility.

In one example, the high current of the pulse test may simulate a sudden breaking action of an electric vehicle. To simulate the sudden breaking, a 500 A current, for example, is injected into battery under test 104 for 10-40 seconds (preferably for 20 seconds). Injection of the high current may lead to rapid charging of battery under test 104. When battery under test 104 is charging, opposition battery 106 may discharge due to its opposition configuration. However, a rate and an amount of discharge of opposition battery 106 is lower than that of battery under test 104 because of a relatively larger capacity. Slower discharging of opposition battery 104 helps in maintaining a relatively stable voltage difference at terminals of power cycler 102.

In another example, the high current of the pulse test may simulate a rapid acceleration action of an electric vehicle. To simulate the rapid acceleration, a 500 A current, for example, is withdrawn from battery under test 104 for 10-40 seconds (preferably for 20 seconds). Withdrawal of the high current may cause rapid discharge battery under test 104. When battery under test 104 is discharging, opposition battery 106 may charge due to its opposition configuration. However, a rate and an amount of charging of opposition battery 106 is lower than that of battery under test 104 because of a relatively larger capacity. Slower charging of opposition battery 106 helps in maintaining a relatively stable voltage difference at terminals of power cycler 102.

Performance of battery under test 104 is measured during the pulse test. For example, a temperature, a rate of increase of temperature, a state of charge, a rate of increase of charge, an amount of charging current, a rate of charging/discharging, etc. may continuously be measured by plurality of sensors 112 when simulating the rapid breaking and rapid acceleration. The measured parameters from the pulse test are used to determine a status of battery under test 104. For example, the measured parameters may be used to determine whether battery under test 104 is degraded, not degraded, or partially degraded.

If the any of these parameters are above a maximum threshold for battery under test 104 during the pulse test, first controller 108 may alert power cycler 102 of the same and first controller 108 or power cycler 102 may alter the pulse test. For example, power cycler 102, upon detecting unusual temperature rise in battery under test 104, may decrease the current being injected/withdrawn into battery under test 104 or suspend the pulse test.

The cycle test may include completely charging and completely discharging battery under test 104. For example, power cycler 102 may inject a charging current into battery under test 104 until battery under test 104 is completely charged. When running a discharge cycle test, power cycler may withdraw a discharge current from battery under test 104 until battery under test 104 is completely discharged. During cycle test (that is, complete charge and discharge cycle), plurality of sensor 112 may measure battery parameters, for example, a charging/discharge current, a temperature, a state of charge/discharge, a rate of charge/discharge, etc. continuously. The measured parameters from the cycle tests are used to determine a status of battery under test 104. For example, the measured parameters may be used to determine whether battery under test 104 is degraded, not degraded, or partially degraded.

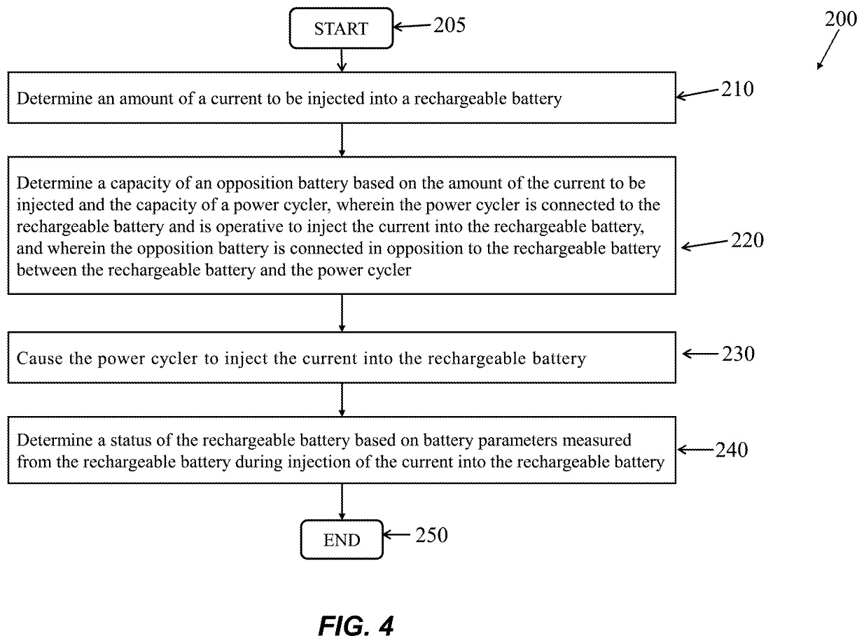

FIG. 4 is a flow chart setting forth the general stages involved in a method 200 consistent with an embodiment of the disclosure for testing of a rechargeable battery. Method 200 may be performed by first controller 108, second controller 110, or power cycler 102. Ways to implement the stages of method 200 will be described in greater detail below.

Method 200 begins at starting block 205 and proceeds to stage 210 where first controller 108 determines an amount of a current to be injected into a rechargeable battery (that is, battery under test 104). In some examples, the amount of current to be injected is determined based on a type of test to be run (that is, a pulse test or a cycle test) and specifications of battery under test 104. For example, for 800V rated battery under test 104, a 500 A current may be injected for 20 ms to conduct a pulse test. The specification of the battery under test 104 may include a voltage rating, a maximum current rating, a charge capacity, a temperature rating, etc. The specification for battery under test 104 may be determined from a make and model number or a specification data associated with battery under test 104. The type of test to be conducted may be provided to first controller 108. Similarly, the specification data may be provided to first controller 108. First controller 108 may determine the amount of the current to be injected based on the type of test and the specification data of battery under test 104. In some examples, the specification data may be determined by scanning a bar code on battery under test 104.

After determining the amount of current at block 210, method 200 proceeds to bloc 220 where first controller 108 determines a capacity of opposition battery 106 based on the amount of the current to be injected and the capacity of power cycler 102. As discussed above, power cycler 102 is connected to the rechargeable battery (that is, battery under test 104) and is operative to inject the determined amount of the current into the rechargeable battery (that is, battery under test 104). Opposition battery 106 is connected in opposition to the rechargeable battery (that is, battery under test 104) between the rechargeable battery (that is, battery under test 104) and power cycler 102.

Capacity of power cycler 102 may include a voltage rating of power cycler 102 and a capacity of a grid connection available to power cycler 103. In one example, power cycler 102 may be rated at 400V. To inject 500 A at 400V may require a grid connection of 200 KVA (500 A×400V). Hence, if the available capacity of the grid connection is lower than 200 KVA, then such test may be not conducted using the available grid connection. In addition, a 400V rated power cycler 102 may only be used to charge or discharge a battery which is rated lower than 400V across terminals of power cycler 102. Hence, first controller 108 may determine opposition battery 106 to be at least 400V for testing battery under test 104 of 800V. By connecting opposition battery 106 at 400V or higher in opposition to battery under test 104 that is rated at 800V may reduce the voltage across terminals of power cycler 102 to at least 400V for testing of battery under test 104. By further reducing the voltage across terminals of power cycler 102 may further reduce the grid connection requirements. For example, by reducing the voltage across terminals of power cycler 102 to 50V may reduce the grid connection requirements to 25 KVA (500 A×50V) from 200 KVA at 400V. However, a substantially low voltage across terminals of power cycler 102 may lead to very slow charge/discharge of battery under test 104 thereby compromising the effectiveness of the test. Therefore, a range for the voltage across terminals of power cycler 102 is defined based on the voltage rating of power cycler 102, voltage rating of battery under test 104, and a capacity of the grid connection available to power cycler 102. The range can be between 50V and a maximum voltage rating of power cycler 102. First controller 108 may determine the capacity of opposition battery 106 based on the amount of the current to be injected, the voltage rating of power cycler 102, the voltage rating of battery under test 104, and the capacity of the grid connection available to power cycler 102.

Once having determined the capacity of opposition battery 106 at stage 220, method 200 may proceed to stage 230 where first controller 108 causes power cycler 102 to inject the determined amount of the current into the rechargeable battery (that is, battery under test 104). For example, first controller 108 may send a trigger signal to power cycler 102 to start injecting the determined amount of current to battery under test 104.

After causing power cycler 102 to inject the determined amount of current at stage 230, method 200 proceeds to stage 240 where first controller 108 determines a status of the rechargeable battery (that is, battery under test 104). The status is determined based on battery parameters measured from the rechargeable battery (that is, battery under test 104) in response to the current being injected into the rechargeable battery (that is, battery under test 104). For example, plurality of sensors 112 may continuously measure an amount of current, a rate of change of current, a rate of change of voltage, a temperature, a rate of change of temperature, etc. of battery under test 104. The measurements can be provided to first controller 108.

First controller 108 may compare these measurements with expected measurements to determine any deviations or variations. A status of battery under test 104 is then determined based on the determined deviations. For example, battery under test 104 is determined to be good or not degraded (useable) if the deviations are less than a first predetermined limit. On the other spectrum, battery under test 104 is determined to be degraded (unusable) if the deviations are greater than a second predetermined limit. In some examples, battery under test 104 is determined to be partially degraded if the deviations are between the first predetermined limit and the second predetermined limit. Each of the first predetermined limit and second predetermined limits can be defined for each of a plurality of measurable parameters. In such scenarios, an average overall deviation may be determined to determine the status of battery under test 104. In some examples, the level of degradation may be determined for each battery modules of battery under test 104.

Unusable rechargeable batteries 104 or battery modules of rechargeable battery 104 are sent to a recycler to extract and re-use the materials, such as nickel, contained within the cells of the rechargeable battery packs. Usable rechargeable battery 104 or useable modules on rechargeable battery 104 can be reused. In one instant, a new battery pack may be formed by taking usable battery modules from multiple rechargeable batteries 104.

FIG. 5 shows computing device 300. As shown in FIG. 5, computing device 300 includes a processing unit 310 and a memory unit 315. Memory unit 315 includes a software module 320 and a database 325. While executing on processing unit 310, software module 320 performs, for example, processes for testing a rechargeable battery, including for example, any one or more of the stages from method 200 described above with respect to FIG. 4. Computing device 300, for example, provides an operating environment for power cycler 102, first controller 108, second controller 110, and plurality of sensors 112. Power cycler 102, first controller 108, second controller 110, and plurality of sensors 112 may operate in other environments and are not limited to computing device 300.

Computing device 300 can be implemented using a tablet device, a mobile device, a smart phone, a telephone, a remote control device, a personal computer, a network computer, a mainframe, a router, a switch, a server cluster, a smart TV-like device, a network storage device, a network relay device, or other similar microcomputer-based device. Computing device 300 can include any computer operating environment, such as hand-held devices, multiprocessor systems, microprocessor-based or programmable sender electronic devices, minicomputers, mainframe computers, and the like. Computing device 300 can also be practiced in distributed computing environments where tasks are performed by remote processing devices. The aforementioned systems and devices are examples and computing device 300 can comprise other systems or devices.

Embodiments of the disclosure, for example, can be implemented as a computer process (method), a computing system, or as an article of manufacture, such as a computer program product or computer readable media. The computer program product can be a computer storage media readable by a computer system and encoding a computer program of instructions for executing a computer process. The computer program product can also be a propagated signal on a carrier readable by a computing system and encoding a computer program of instructions for executing a computer process. Accordingly, the present disclosure can be embodied in hardware and/or in software (including firmware, resident software, micro-code, etc.). In other words, embodiments of the present disclosure can take the form of a computer program product on a computer-usable or computer-readable storage medium having computer-usable or computer-readable program code embodied in the medium for use by or in connection with an instruction execution system. A computer-usable or computer-readable medium can be any medium that can contain, store, communicate, propagate, or transport the program for use by or in connection with the instruction execution system, apparatus, or device.

The computer-usable or computer-readable medium can be, for example but not limited to, an electronic, magnetic, optical, electromagnetic, infrared, or semiconductor system, apparatus, device, or propagation medium. More specific computer-readable medium examples (a non-exhaustive list), the computer-readable medium can include the following: an electrical connection having one or more wires, a portable computer diskette, a random access memory (RAM), a read-only memory (ROM), an erasable programmable read-only memory (EPROM or Flash memory), an optical fiber, and a portable compact disc read-only memory (CD-ROM). Note that the computer-usable or computer-readable medium could even be paper or another suitable medium upon which the program is printed, as the program can be electronically captured, via, for instance, optical scanning of the paper or other medium, then compiled, interpreted, or otherwise processed in a suitable manner, if necessary, and then stored in a computer memory.

While certain embodiments of the disclosure have been described, other embodiments may exist. Furthermore, although embodiments of the present disclosure have been described as being associated with data stored in memory and other storage mediums, data can also be stored on or read from other types of computer-readable media, such as secondary storage devices, like hard disks, or a CD-ROM, a carrier wave from the Internet, or other forms of RAM or ROM. Further, the disclosed methods' stages may be modified in any manner, including by reordering stages and/or inserting or deleting stages, without departing from the disclosure.

Furthermore, embodiments of the disclosure may be practiced in an electrical circuit comprising discrete electronic elements, packaged or integrated electronic chips containing logic gates, a circuit utilizing a microprocessor, or on a single chip containing electronic elements or microprocessors. Embodiments of the disclosure may also be practiced using other technologies capable of performing logical operations such as, for example, AND, OR, and NOT, including but not limited to, mechanical, optical, fluidic, and quantum technologies. In addition, embodiments of the disclosure may be practiced within a general purpose computer or in any other circuits or systems.

Embodiments of the disclosure may be practiced via a system-on-a-chip (SOC) where each or many of the element illustrated in FIGS. 1 and 2 may be integrated onto a single integrated circuit. Such a SOC device may include one or more processing units, graphics units, communications units, system virtualization units and various application functionality all of which may be integrated (or “burned”) onto the chip substrate as a single integrated circuit. When operating via a SOC, the functionality described herein with respect to embodiments of the disclosure, may be performed via application-specific logic integrated with other components of computing device 400 on the single integrated circuit (chip).

Embodiments of the present disclosure, for example, are described above with reference to block diagrams and/or operational illustrations of methods, systems, and computer program products according to embodiments of the disclosure. The functions/acts noted in the blocks may occur out of the order as shown in any flowchart. For example, two blocks shown in succession may in fact be executed substantially concurrently or the blocks may sometimes be executed in the reverse order, depending upon the functionality/acts involved.

While the specification includes examples, the disclosure's scope is indicated by the following claims. Furthermore, while the specification has been described in language specific to structural features and/or methodological acts, the claims are not limited to the features or acts described above. Rather, the specific features and acts described above are disclosed as example for embodiments of the disclosure.

What is claimed is:

1. A system for testing a rechargeable battery, the system comprising:
a power cycler comprising a negative terminal and a positive terminal;
a rechargeable battery comprising a negative terminal and a positive terminal, wherein the negative terminal of the rechargeable battery is connected to the negative terminal of the power cycler; and
an opposition battery comprising a negative terminal and a positive terminal, wherein the positive terminal of the opposition battery is connected to the positive terminal of the rechargeable battery, wherein the negative terminal of the opposition battery is connected to the positive terminal of the power cycler, and wherein the power cycler is configured to inject a predetermined amount of current to the rechargeable battery.

2. The system of claim 1, wherein the power cycler is connected to a power grid.

3. The system of claim 2, wherein the power cycler is configured to withdraw power from and recycle power back to the power grid.

4. The system of claim 1, wherein a capacity of the opposition battery is at least five times of a capacity of the rechargeable battery.

5. The system of claim 1, wherein the opposition battery has a lower voltage rating than the rechargeable battery.

6. The system of claim 1, wherein a capacity of the opposition battery is dynamically reconfigurable.

7. The system of claim 1, wherein the predetermined amount of current comprises a pulse current representative of a sudden breaking of an electric vehicle.

8. The system of claim 1, wherein the predetermined amount of current comprises a pulse current representative of a sudden acceleration of an electric vehicle.

9. The system of claim 1, further comprising a plurality of sensors configured to measure a performance of the battery under test when the predetermined amount of current is being injected to the rechargeable battery.

10. A method of determining a status of a rechargeable battery, the method comprising:
determining an amount of a current to be injected into a rechargeable battery;
determining a capacity of an opposition battery based on the amount of the current to be injected and the capacity of a power cycler, wherein the power cycler is connected to the rechargeable battery and is operative to inject the current into the rechargeable battery, and wherein the opposition battery is connected in opposition to the rechargeable battery between the rechargeable battery and the power cycler;
causing the power cycler to inject determined amount of the current into the rechargeable battery; and
determining a status of the rechargeable battery based on battery parameters measured from the rechargeable battery during injection of the current into the rechargeable battery.

11. The method of claim 10, further comprising:
adjusting the capacity of the opposition battery when the pulse current is being injected into the rechargeable battery.

12. The method of claim 10, wherein determining the status of the rechargeable battery based on the battery parameters measured from the rechargeable battery during injection of the current into the rechargeable battery comprises determining that the rechargeable battery is completely degraded.

13. The method of claim 10, wherein determining the amount of the current to be injected into the rechargeable battery comprises determining the amount of the current to be injected into the rechargeable battery to simulate a pulse current generated during sudden breaking of a vehicle associated with the rechargeable battery.

14. The method of claim 10, wherein determining the amount of the current to be injected into the rechargeable battery comprises determining the amount of the current to be injected into the rechargeable battery to simulate a pulse current generated during sudden acceleration of a vehicle associated with the rechargeable battery.

15. The method of claim 10, wherein determining the capacity of the opposition battery comprises determining the capacity of the opposition battery further based on the capacity of the rechargeable battery and a capacity of a grid connection to the power cycler.

16. An apparatus for determining a status of a rechargeable battery, the apparatus comprising:
a memory device; and
a processing unit connected to the memory device, wherein the processing unit is operative to:
determine an amount of a pulse current to be injected into a rechargeable battery;
determine a capacity of an opposition battery based on the amount of the pulse current to be injected and a capacity of a power cycler, wherein the power cycler is connected to the rechargeable battery and is operative to inject the pulse current into the rechargeable battery, and wherein the opposition battery is connected in opposition to the rechargeable battery between the rechargeable battery and the power cycler;
cause the power cycler to inject the pulse current into the rechargeable battery; and
determine a status of the rechargeable battery based on battery parameters measured from the rechargeable battery in response to the pulse current being injected into the rechargeable battery.

17. The apparatus of claim 16, wherein the processing unit is further operative to:
determine a voltage rating of the opposition battery based on a voltage rating of the rechargeable battery and a voltage rating of the power cycler.

18. The apparatus of claim 16, wherein the voltage rating of the opposition battery is 100V lower than the voltage rating of the rechargeable battery.

19. The apparatus of claim 16, wherein the capacity of the opposition battery is at least 5 times of the capacity of the rechargeable battery.

20. The apparatus of claim 16, wherein the processing unit if further operative to:
cause adjusting the capacity of the opposition battery when the pulse current is being injected into the rechargeable battery.
